(19) United States
(12) Patent Application Publication
(10) Pub. No.: US 2007/0092987 A1
(43) Pub. Date: Apr. 26, 2007

(54) Conductive electrode powder, a method for preparing the same, a method for preparing an electrode of a plasma display panel by using the same, and a plasma display panel comprising the same

(76) Inventor: Chul-Hong Kim, Suwon-si (KR)

Correspondence Address: Robert E. Bushnell, Suite 300, 1522 K Street, N.W., Washington, DC, 20005, US

(21) Appl. No.: 11/505,316

(22) Filed: Aug. 17, 2006

(30) Foreign Application Priority Data
Sep. 30, 2005 (KR) 10-2005-0092243

(51) Int. Cl. H01L 21/00; G03G 21/00; H01L 23/58

(52) U.S. Cl. 438/82; 257/642; 399/350

(57) ABSTRACT

The present invention provides a conductive electrode powder which includes electroconductive metal particles, and an inorganic oxide coating layer covering the surface of the electroconductive metal particles. By using a conductive electrode powder, the corrosion, the ionization, the migration such as ionization, and yellowing of the electrode such as colloidalization can be prevented, while simultaneously maintaining electrical conductivity of an electrode.

### CROSS-REFERENCE TO RELATED APPLICATION AND CLAIM OF PRIORITY

This application claims priority to and the benefit of Korean Patent Application No. 10-2005-0092243 filed in the Korean Intellectual Property Office on Sep. 30, 2005, the entire content of which is incorporated herein by reference.

### BACKGROUND OF THE INVENTION

1. Field of the Invention

The present invention relates to a conductive electrode powder, a method of preparing the same, a method for forming an electrode of a plasma display panel, and a plasma display panel including the same. More particularly, the present invention relates to a conductive electrode powder that can inhibit oxidation of exposed ends of address electrodes and bus electrodes, a method of preparing the same, a method for forming an electrode of a plasma display panel, and a plasma display panel including the same.

2. Description of the Related Art

A plasma display panel (PDP) is a flat display device using a plasma phenomenon, which is also called a gas-discharge phenomenon since a discharge is generated in the panel when a potential greater than a certain level is applied to two electrodes that are separated from each other under a gas atmosphere in a non-vacuum state.

Such gas-discharge phenomenon is applied to display an image in the plasma display panel. At present, a generally used plasma display panel is a reflective alternating current driven plasma display panel. On a rear substrate (hereinafter referred to as a “first substrate”), phosphor layers are formed in discharge cells compartmentalized by barrier ribs. Display electrodes and a dielectric layer covering the display electrodes are formed on a front substrate (hereinafter referred to as a “second substrate”).

The above plasma display panel is formed by positioning the first substrate and the second substrate a predetermined distance apart and substantially parallel with each other, like other flat panel display devices such as a vacuum fluorescence display (VFD) or a field emission display (FED). The substrates are joined using an adhesive along their circumferences to form a discharge cell in a vacuum state.

Thus far, the first substrate and the second substrate of a plasma display panel are assembled with a seal frit. In a mounting process, a driver integrated circuit (IC) package such as a tape carrier package (TCP) is adhered to an anisotropic conductive film (ACF).

However, a plasma display panel has a considerable time gap until it is assembled with a module after the plasma display panel itself is assembled, during which an exposed electrode thereof is easily corroded by oxidation or sulfuration due to moisture, impurities, and external gases such as oxygen or sulfur dioxide generated by applying an electric field or being left alone in the air. The aforementioned corrosion problem of a terminal element resultantly accelerates the ionization of the exposed electrode (particularly one made with silver (Ag)), which subsequently leads ions to migrate between the electrodes and causes a short-circuit. On the other hand, a sulfur component generates silver sulfide at the silver electrode, resultantly causing the silver electrode to be cut off. This terminal element inferiority leads to inferior panels.

Various attempts have been made to prevent this inferiority. However, they are mostly limited to indirect ways of isolating impurities, water, moisture, and external gases, but this does not deal with fundamental ways of imparting anti-corrosion to an electrode itself.

### SUMMARY OF THE INVENTION

Embodiments of the present invention provide an improved conductive electrode powder, a method for preparing the conductive electrode powder, a method for preparing an electrode of a plasma display panel, and an improved plasma display panel.

An embodiment of the present invention provides a conductive electrode powder that includes electroconductive metal particles coated with inorganic oxide.

Another embodiment of the present invention provides a method of preparing a conductive electrode powder.

Another embodiment of the present invention provides a method of forming an electrode using the conductive electrode powder.

Another embodiment of the present invention provides a plasma display panel which includes the electrode formed using the conductive electrode powder.

According to an embodiment of the present invention, a conductive electrode powder is provided, which includes electroconductive metal particles and an inorganic oxide coating layer covering the surface of the electroconductive metal particles.

According to another embodiment of the present invention, a method of preparing a conductive electrode powder is provided, which includes preparing an inorganic oxide dispersion by dispersing inorganic oxide particles in a dispersion solvent, mixing electroconductive metal particles with the inorganic oxide dispersion to obtain a mixture, and forming a powder from the mixture, preferably by spraying the mixture and firing it, to obtain the conductive electrode powder.

According to still another embodiment of the present invention, a method of forming an electrode on a substrate of a plasma display panel is provided, which includes: preparing electroconductive metal particles having an inorganic oxide coating layer covering the surface of the electroconductive metal particles; and applying the electroconductive metal particles having the inorganic oxide coating layer on the substrate of the plasma display panel.

According to yet another embodiment of the present invention, a method of forming an electrode on a substrate of a plasma display panel is provided, which includes: preparing a photosensitive vehicle by mixing a polymer resin, a photopolymerizable monomer, a photopolymerization initiator, and a solvent; preparing a photosensitive composition by mixing a conductive electrode powder comprising electroconductive metal particles and an inorganic oxide coating layer covering the surface of the electroconductive metal particles with the photosensitive vehicle; coating the photosensitive composition on a substrate; and drying, exposing, developing, and firing the photosensitive composition on the substrate.

According to still another embodiment of the present invention, a method of forming an electrode of a plasma display panel is provided, which includes preparing a photosensitive vehicle by mixing a polymer resin, a photopolymerizable monomer, a photopolymerization initiator, a solvent, and inorganic oxide; preparing a photosensitive composition by mixing electroconductive metal particles and the photosensitive vehicle; coating the photosensitive composition on a substrate; and performing drying, exposing, developing, and firing operations.

According to another embodiment of the present invention, a method of forming a plasma display panel is provided, which includes: preparing a first plate having address electrodes; and preparing a second plate having display electrodes, the display electrodes comprising transparent electrodes and bus electrodes, wherein at least one of the address electrodes and the bus electrodes is prepared by preparing electroconductive metal particles having an inorganic oxide coating layer covering the surface of the electroconductive metal particles and applying the electroconductive metal particles having the inorganic oxide coating layer on a substrate of the plasma display panel.

According to still another embodiment of the present invention, the present invention provides a plasma display panel including a first plate which is comprised of a first substrate, an address electrode formed on the first substrate, a dielectric layer covering the address electrode, barrier ribs formed on the dielectric layer, and a phosphor layer positioned inside a discharge cell formed with the barrier ribs; and a second plate facing the first plate, the second plate which is comprised of a second substrate, a display electrode which is comprised of a transparent electrode and a bus electrode and which is formed on the second substrate, a transparent dielectric layer covering the display electrode, and a protective layer coated on the transparent dielectric layer, wherein at least one of the address electrode or the bus electrode includes electroconductive metal particles and an inorganic oxide coating layer covering the surface of the electroconductive metal particles.

### BRIEF DESCRIPTION OF THE DRAWINGS

A more complete appreciation of the embodiments of the invention and many of the attendant advantages thereof, will be readily apparent as the same becomes better understood by reference to the following detailed description when considered in conjunction with the accompanying drawings in which like reference symbols indicate the same or similar components, wherein:

FIG. 1 is a partial exploded perspective view showing the structure of a plasma display panel;

FIG. 2 is a schematic cross-sectional view showing a connection structure of terminal elements of address electrodes, a driver IC package, and an ACF;

FIG. 3 is a flow chart showing a process of preparing a photosensitive composition;

FIG. 4 is a scanning electron microscope (SEM) photograph showing uncoated silver (Ag) powder;

FIG. 5 is a light microscope photograph showing a surface of an address electrode after firing that is fabricated according to Comparative Example 1;

FIG. 6 is a scanning electron microscope (SEM) photograph showing conductive electrode powder having a silica coating later according to Example 1;

FIG. 7 is a light microscope photograph showing a surface of an address electrode after firing that is fabricated according to Example 2; and

FIG. 8 is a light microscope photograph showing a surface of an address electrode after firing that is fabricated according to Example 3.

### DETAILED DESCRIPTION OF THE INVENTION

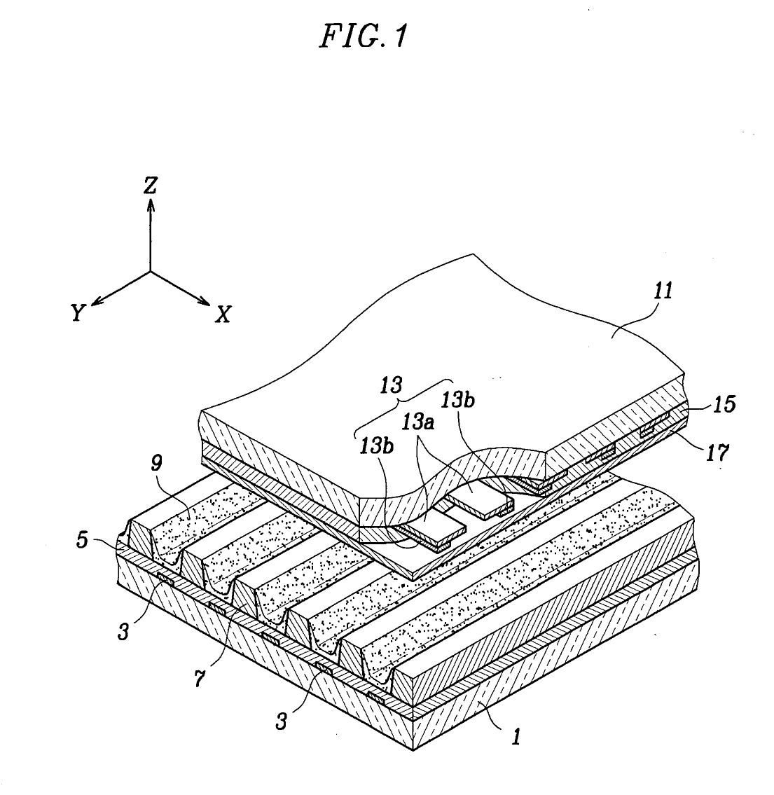

FIG. 1 is a partial exploded perspective view showing a plasma display panel according to one embodiment of the present invention. Referring to the drawing, the plasma display panel includes address electrodes 3 formed on a first substrate 1 in one direction (Y direction in the drawing) and a dielectric layer 5 covering the address electrodes on the entire surface of the first substrate. Then, barrier ribs 7 are formed on the dielectric layer 5 and between the address electrodes 3. The barrier ribs 7 can be open-type barrier ribs or closed-type barrier ribs. Next, red, green, and blue phosphor layers 9 are each positioned between barrier ribs 7.

A second substrate 11 includes a pair of display electrodes 13 comprising a transparent electrode 13a and a bus electrode 13b formed in a direction crossing the address electrodes 3 (X direction in the drawing), and a transparent dielectric layer 15 and a protective layer 17 covering the display electrodes 13 on its surface opposing the first substrate 1. Accordingly, when the first and second substrates are assembled, discharge cells are formed where the address electrodes 3 are crossed with the display electrodes 13 at right angles. The discharge cells are filled with a discharge gas.

In this way, when an address discharge is performed by applying an address voltage (Va) between the address electrode 3 and one display electrode 13 and a maintenance voltage (Vs) is applied between a pair of display electrodes 13, the display panel emits visible rays through the transparent front substrate 11 as vacuum ultraviolet rays generated during a maintenance discharge excite the phosphor layers 9.

The plasma display panel is formed by assembling the first and second substrates with a seal frit. Here, a driver IC package 24 and an ACF 25 are compressed and fixed with a terminal element of the address electrode.

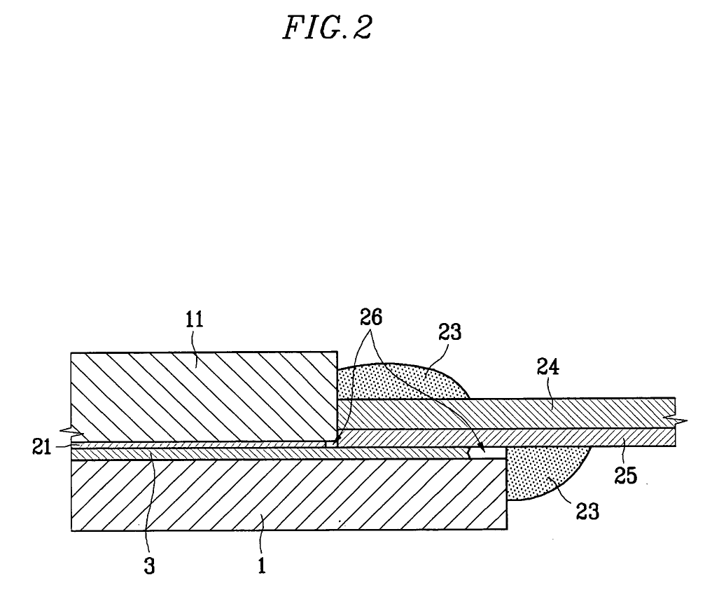

FIG. 2 is a schematic view showing a cross-section of the area where the driver IC package and the ACF are connected with a terminal element of an address electrode of a plasma display panel. As shown in FIG. 2, a first substrate 1 is assembled with a second substrate 11 by a seal frit 21, wherein a terminal element of an address electrode 3 is compressed with a driver IC package (e.g., a tape carrier package (TCP)) 24 and an ACF 25 which are supported by an adhesive agent 23. Here, the first and second substrates 1 and 11 can sometimes have an unnecessary space 26 at the TCP 24 and the ACF 25. The space can cause an electrode exposed thereto to be oxidized or sulfurized.

However, the structure of the area where a terminal element of an address electrode of a plasma display panel is connected with a driver IC package and ACF is not necessarily limited to as shown in FIG. 2.

The address electrode and the bus electrode of the plasma display panel preferably include at least one metal selected from the group consisting of silver (Ag), gold, palladium, platinum, copper, aluminum, tungsten, molybdenum, an alloy of two or more materials selected therefrom, and a combination thereof. Here, silver (Ag) has the best electroconductivity and is the most preferable for an address electrode and a bus electrode.

The following reaction schemes 1 to 5 show the oxidation processes of a silver (Ag) electrode, and thereby the movement phenomenon of silver (Ag).

Reaction Scheme 1

Ag->Ag⁺

Reaction Scheme 2

H₂O->H⁺+OH⁻

Reaction Scheme 3

Ag⁺+OH⁻->AgOH

Reaction Scheme 4

2AgOH->Ag₂O+H₂O

Reaction Scheme 5

Ag₂O+H₂O->2AgOH->2Ag⁺+2OH⁻

When a plasma display panel is assembled, a terminal element of an electrode that is externally exposed is easily ionized by applied voltage and moisture (Reaction Scheme 1). Here, the moisture in air is easily separated into protons (H⁺) and hydroxide ions (OH⁻) (Reaction Scheme 2), and then the hydroxide ions are bound with silver ions (Ag⁺) to form silver hydroxide (AgOH) (Reaction Scheme 3).

The silver hydroxide (AgOH) is very unstable such that it easily forms a sulfur or black silver oxide (Ag₂O) (Reaction Scheme 4). The resulting silver oxide has a continuous reversible reaction (Reaction Scheme 5), entailing a silver migration phenomena in which the silver gradually moves.

Silver sulfide is produced in a very similar mechanism to that of the silver oxide.

In this way, a corrosion layer formed by oxidizing or sulfurizing an address electrode may increase resistances and also cause terminal element and panel inferiority.

Therefore, the present invention provides a conductive electrode powder for preventing the corrosion. The conductive electrode powder includes electroconductive metal particles and an inorganic oxide coating layer covering the electroconductive metal particles.

As for the electroconductive metal particles, any metal particle with excellent electroconductivity can be used, but it is preferable to include at least one selected from the group consisting of silver (Ag), gold, palladium, platinum, copper, aluminum, tungsten, molybdenum, and an alloy formed of two or more thereof. Here, silver (Ag) is most preferable due to its excellent electroconductivity.

The electroconductive metal particles may have an average diameter ranging from 10 nm to 5 μm. When the electroconductive metal particles have an average particle diameter of less than 10 nm it is not economically advantageous, while when they have an average particle diameter of over 5 μm they have a reduced surface area which causes a loss of electroconductivity.

The inorganic oxide includes, but is not limited to, silica, alumina, titania, zirconia, or combinations thereof. The inorganic oxide is preferably silica.

The electroconductive metal particles are coated with an inorganic oxide coating layer preferably ranging in thickness of less than or equal to 1 μm, preferably 10 to 500 nm, and more preferably from 10 to 50 nm. When it is more than 1 μm thick, electroconductive performance characteristics can be reduced when forming an electrode. When the inorganic oxide coating layer is less than 10 nm thick its anti-corrosion performance characteristics deteriorate. The inorganic oxide coating layer is preferably formed as a single layer.

In addition, the inorganic oxide coating layer has insulating characteristics, which continuously prevent an electrode of a plasma display panel from corroding during its fabrication process. Later, the inorganic oxide coating layer is destroyed, for example, by pressure, when it is bonded with a TCP and the like during the mounting process, recovering electroconductivity.

The conductive powder for forming an electrode can be prepared with a method of preparing an inorganic oxide dispersion solution by dispersing inorganic oxide particles into a dispersion solvent, adding and mixing electroconductive metal particles with the inorganic oxide dispersion solution, and forming a powder from the mixture to obtain the conductive powder. The powder can be formed by spraying the mixture, for example, using a thermal spray method, and firing the sprayed mixture.

The inorganic oxide particles used for preparing the inorganic oxide dispersion solution are preferably added at 5 to 30 parts by weight based on 100 parts by weight of the dispersion solution. When the inorganic oxide particles are included at less than 5 parts by weight it is difficult to form a coating layer, while when the inorganic oxide particles are included at more than 30 parts by weight the coating layer has inferior quality.

Non-limiting examples of the dispersion solvent include at least one selected from the group consisting of ethanol, trimethyl pentanediol monoisobutyrate (TPM), butylcarbitol (BC), butyl cellosolve (BC), butyl carbitol acetate (BCA), a terfenol isomer, terpineol (TP), toluene, texanol, and combinations thereof.

In addition, the inorganic oxide particles are preferably included at 2 to 10 parts by weight based on 100 parts by weight of the electroconductive metal particles. When the amount of the inorganic oxide particles is less than 2 parts by weight the coating layer cannot be sufficiently thick, while when the amount of the inorganic oxide particles are more than 10 parts by weight the coating layer can be unnecessarily thick.

For the electroconductive metal particles used in a method of preparing the conductive powder for forming an electrode, any metal particle with good electroconductivity can be used, but it is preferable to use at least one selected from the group consisting of silver (Ag), gold, palladium, platinum, copper, aluminum, tungsten, molybdenum, and an alloy formed of two or more thereof. Here, silver (Ag) is the most preferable due to its excellent electroconductivity.

In addition, the inorganic oxide particles preferably have an average diameter ranging of less than or equal to 1 μm, preferably 10 to 500 nm, and more preferably from 10 to 50 nm. The smaller the average diameter of the inorganic oxide particle is, the more preferable it is. When it is more than 500 nm, it is difficult to obtain a uniform coating layer while when it is less than 10 nm, it is difficult to obtain inorganic oxide particles having such average diameter.

The mixture solution is preferably fired at 500 to 600° C. for 40 to 100 minutes, and more preferably at 550 to 580° C. for 60 to 80 minutes.

The conductive electrode powder produced as above may be used in an ink-jet method, an off-set method, a photosensitive paste method, a direct printing method, and a transfer materials technology (TMT) method for fabricating a plasma display panel.

The photosensitive paste method has been used for forming a thin membrane, but it is now applied to a thick film. The method includes applying a photosensitive paste composition (also referred to as photosensitive composition) to a substrate, projecting ultraviolet rays thereon with a photo mask and developing it, and then removing the unhardened part to form a pattern.

A method of forming an electrode of a plasma display panel according to an embodiment of the present invention includes preparing a vehicle by mixing a polymer resin, a photopolymerizable monomer, a photopolymerization initiator, and a solvent, preparing a photosensitive paste composition by mixing the vehicle with the conductive electrode powder, printing the photosensitive paste composition on a substrate, and drying, exposing, developing, and firing the printed photosensitive paste.

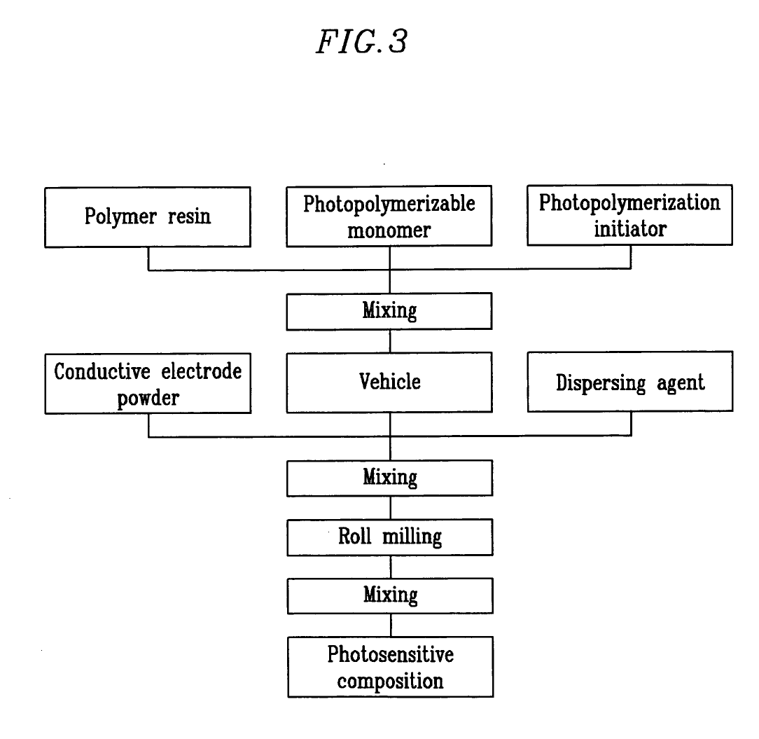

FIG. 3 is a work flow chart of preparing the photosensitive paste composition according to the embodiment of the present invention. The printing, drying, exposing, and developing processes are the same as those in fabricating an electrode of a common plasma display panel, which needs no more detailed description. However, the firing is preferably performed at 500 to 600° C. for 40 to 100 minutes, and more preferably at 550 to 580° C. for 60 to 80 minutes.

The photosensitive paste composition is prepared by mixing the conductive electrode powder and the photosensitive vehicle in a weight ratio of 50 to 80: 50 to 20. The photosensitive vehicle is preferably prepared by mixing a polymer resin, a photopolymerizable monomer, a photopolymerization initiator, and a solvent in a weight ratio of 10 to 40: 5 to 20: 1 to 10: 30 to 70 based on the total weight of the vehicle.

The polymer resin acts as a binder, and it may be obtained by polymerization of at least one compound having carbon-carbon unsaturated bonds. The polymer resin has preferably a weight average molecular weight ranging from 500 to 100,000. According to one embodiment, the polymer resin may include one selected from the group consisting of methacryl polymer, polyester acrylate, trimethylolpropane triacrylate, trimethylolpropane triethoxy triacrylate, cresol epoxy acrylate, a polymethylmethacrylate (PMMA)-polymethylacrylate (PMAA) copolymer, hydroxypropyl cellulose (HPC), ethyl cellulose (EC), polyisobutyl methacrylate, (PIBMA), and a combination thereof.

The photopolymerizable monomer is polymerized by ultraviolet radiation to cure the photosensitive composition. When the photopolymerizable monomer is used in an amount of less than 5 parts by weight based on the vehicle weight, the cure reaction is not sufficient, whereas when it is more than 20 parts by weight based on the vehicle weight, it may have an unfavorable effect on electroconductivity of an electrode.

The photopolymerizable monomer may include an acrylate-based monomer such as epoxy acrylate, polyester acrylate, methylacrylate, ethylacrylate, n-propylacrylate, isopropylacrylate, n-butylacrylate, sec-butylacrylate, sec-butylacrylate, iso-butylacrylate, tert-butylacrylate, n-pentylacrylate, allylacrylate, benzylacrylate, butoxyethylacrylate, butoxytriethyleneglycolacrylate, cyclohexylacrylate, dicyclopentanylacrylate, dicyclopentenylacrylate, 2-ethylhexylacrylate, glycerolacrylate, glycidylacrylate, hepadecafluorodecylacrylate, 2-hydroxyethylacrylate, isobonylacrylate, 2-hydroxypropylacrylate, isodecylacrylate, isooctylacrylate, laurylacrylate, 2-methoxyethylacrylate, methoxyethyleneglycolacrylate, methoxydiethyleneglycolacrylate, or a combination thereof.

The photopolymerization initiator induces the photopolymerization reaction. When the amount of the photopolymerization initiator is less than 1 wt % the polymerization rate is slow, whereas when it is more than 10 wt % the photopolymerization rate may be faster than is necessary, resulting in non-uniformity of a pattern and deterioration of electrode properties.

Non-limiting examples of the photopolymerization initiator include at least one selected from the group consisting of benzophenone, methyl o-benzoyl benzoate, 4,4-bis(dimethylamine)benzophenone, 4,4-bis(diethylamino)benzophenone, 4,4-dichlorobenzophenone, 4-benzoyl-4-methyldiphenyl ketone, dibenzyl ketone, fluorenone, 2,2-diethoxyacetophenone, 2,2-dimethoxy-2-phenylacetophenone, 2-hydroxy-2-methylpropinophenone, p-t-butyidichloroacetophenone, thioxanthone, 2-methylthioxanthone, 2-chlorothioxanthone, 2-isopropylthioxanthone, diethylthioxanthone, benzyldimethyl kethanol, benzylmethoxyethyl acetal, benzoin, benzoin methyl ether, benzoin butyl ether, anthraquinone, 2-t-butyl anthraquinone, 2-amylanthraquinone, β-chloroanthraquinone, anthrone, benzanthrone, dibenzosverone, methyleneanthrone, 4-azidebenzalacetophenone, 2,6-bis(p-azidebenzylidene) cyclohexanone, 2,6-bis(p-azidebenzylidene)-4-methylcyclohexanone, 2-phenyl-1,2-butadione-2-(o-methoxycarbonyl) oxime, 2,3-bis(4-diethylaminobenzal) cyclopentanone, 2,6-bis(4-dimethylaminobenzal) cyclohexanone, 2,6-bis(4-dimethylaminobenzal)-4-methylcyclohexanone, Mihira ketone, 4,4-bis(diethylamino)-benzophenone, 4,4-bis(dimethylamino) chalcone, 4,4-bis(diethylamino)chalcone, p-dimethylaminocynnamilidene indanone, p-dimethylamino benzylidene indanone, 2-(p-dimethylaminophenylvinylene)-isonaphtothiazole, 1,3-bis(4-dimethylaminobenzal)acetone, 1,3-carbonyl-bis(4-diethylaminobenzal)acetone, 3,3-carbonyl-bis(7-diethylaminocumaline), N-phenyl-N-ethylethanolamine, N-phenylethanolamine, N-tolyldiethanolamine, N-phenylethanolamine, isoamyl dimethylaminobenzoate, isoamyl diethylaminobenzoate, 3-phenyl-5-benzoylthio-tetrazol, 1-phenyl-5-ethoxycarbonylthio-tetrazol, and combinations thereof.

The photosensitive vehicle may include a solvent generally used in a vehicle, such as ethanol, trimethyl pentanediol monoisobutyrate (TPM), butyl carbitol (BC), butyl cellosolve (BC), butyl carbitol acetate (BCA), a terfenol isomer, terpineol (TP), toluene, texanol, or combinations thereof.

The photosensitive paste composition can additionally include a dispersing agent to promote dispersion of a conductive electrode powder, a polymer resin, a photopolymerizable monomer, and a photopolymerization initiator. The dispersing agent is preferably added in an amount of 0.1 to 5 parts by weight based on 100 parts by weight of the entire photosensitive paste composition.

Furthermore, the photosensitive paste composition can additionally include additives such as an antifoaming agent, an antioxidant, a photopolymerization inhibitor, a plasticizer, a metal powder, and so on. These additives need not always be used, but are used as needed at generally-known amounts. In addition, the photosensitive paste composition can include a non-photosensitive resin such as an epoxy-based resin or a cellulose-based resin such as nitro cellulose.

According to one embodiment of the present invention, a method of fabricating an electrode of a plasma display panel includes preparing a vehicle by mixing a polymer resin, a photopolymerizable monomer, a photopolymerization initiator, a solvent, and inorganic oxide; preparing a photosensitive paste composition by mixing electroconductive metal particles with the vehicle; printing the photosensitive paste composition on a substrate; and drying, exposing, developing, and firing the printed photosensitive paste composition.

The photosensitive paste composition has the same components as described above, and the same amounts as above, so no further detailed description thereof is required.

A plasma display panel of the present invention includes a first plate, which includes a first substrate, an address electrode formed on the first substrate, a dielectric layer covering the address electrode, barrier ribs formed on the dielectric layer, and phosphor layers positioned inside a discharge cell formed with the barrier ribs; and a second plate which includes a second substrate, a display electrode which is formed on the second substrate and is comprised of a transparent electrode and a bus electrode, a transparent dielectric layer covering the entire surface of the display electrode, and a protective layer coated on the transparent dielectric layer. At least one electrode of the address electrode and the bus electrode includes electroconductive metal particles and inorganic oxide covering the electroconductive metal particles.

Furthermore, at least one of the address electrode and the bus electrode preferably includes the conductive electrode powder, which is formed by coating the inorganic oxide on the surface of the electroconductive metal particles.

At least one of the address electrode and the bus electrode is preferably fabricated by a method selected from the group consisting of an ink-jet method, an off-set method, a photosensitive pasting method, a direct printing method, and a transfer materials technology (TMT) method.

The following examples illustrate the present invention in more detail. However, it is understood that the present invention is not limited by these examples.

### EXAMPLES

### Comparative Example 1

A first plate was fabricated by forming an address electrode on a panel glass, a dielectric layer covering the address electrode, barrier ribs positioned on the dielectric layer, and red, green, and blue phosphor layers inside a discharge cell formed with the barrier ribs.

In addition, a transparent electrode was formed by sputtering indium tin oxide (ITO) and then patterning it, on another panel glass.

A photosensitive vehicle was prepared to include 30 parts by weight of a mixing binder comprising a polymethylmethacrylate (PMMA)-polymethylacrylate (PMAA) copolymer, hydroxypropylcellulose (HPC), ethylcellulose (EC), and polyisobutylmethacrylate (PIBMA); 50 parts by weight of a solvent comprising trimethyl pentanediol monoisobutyrate (TPM), butylcarbitol (BC), butyl carbitol acetate (BCA), and a terfenol isomer; 3 parts by weight of 2,2-dimethoxy-2-phenylacetophenone as a photopolymerization initiator, and 17 parts by weight of epoxy acrylate as a photopolymerizable monomer.

Then, a photosensitive paste composition was prepared by mixing 29.8 wt % of the photosensitive vehicle, 65 wt % of an amorphous silver (Ag) powder with an average particle diameter ranging from 1.5 to 3 μm (DOWA MINIG Co., Ltd., a particle-spherical shape), 3 wt % of PbO, 2 wt % of B₂O₃, and 0.2 wt % of silica, and then milling them with a three roll mill.

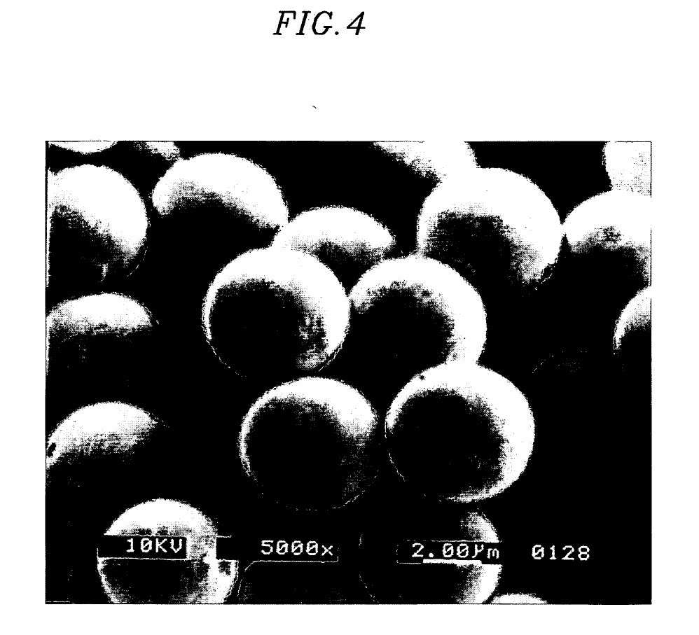

FIG. 4 is a scanning electron microscope (SEM) photograph of a silver (Ag) powder for forming an electrode, which is not coated with silica.

The paste was printed on the entire surface of a transparent electrode using a squeezer and dried.

The prepared paste was exposed with 45 mJ/cm² using a photomask with a predetermined pattern and exposure equipment, and thereafter the predetermined pattern was formed by developing it with a 0.4 wt % aqueous sodium carbonate solution at 35□ sprayed through a nozzle with a spraying pressure of 1.2 kgf/cm² for 25 seconds and then removing the unexposed part. Then, a patterned bus electrode with a thickness of 4 μm was produced by firing the patterned electrode at 550° C. for 60 minutes.

A second substrate was fabricated by forming a transparent dielectric layer covering a bus electrode and the transparent electrode, and then forming a MgO protective layer on the transparent dielectric layer.

The resulting first and second substrates were bound together, and then a plasma display panel was fabricated by evacuating a space therebetween, injecting gas therein, and sealing the injection opening.

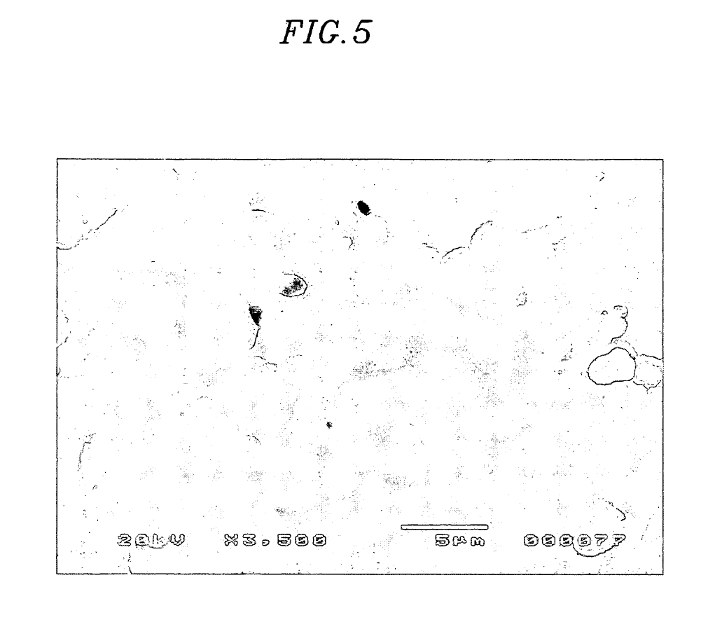

FIG. 5 is a scanning electron microscope (SEM) photograph of the surface of an address electrode according to Comparative Example 1 after firing it.

### Example 1

100 parts by weight of a silica solution (water glass) including 15 wt % of silica particles with an average particle diameter of 50 nm (made by FERRO Co.) were mixed with 300 parts by weight of an amorphous silver (Ag) powder (DOWA MINIG Co., Ltd., particle-spherical shape). Then, the mixture was agitated, sprayed, and fired at 580° C. for 60 minutes to prepare a conductive electrode powder.

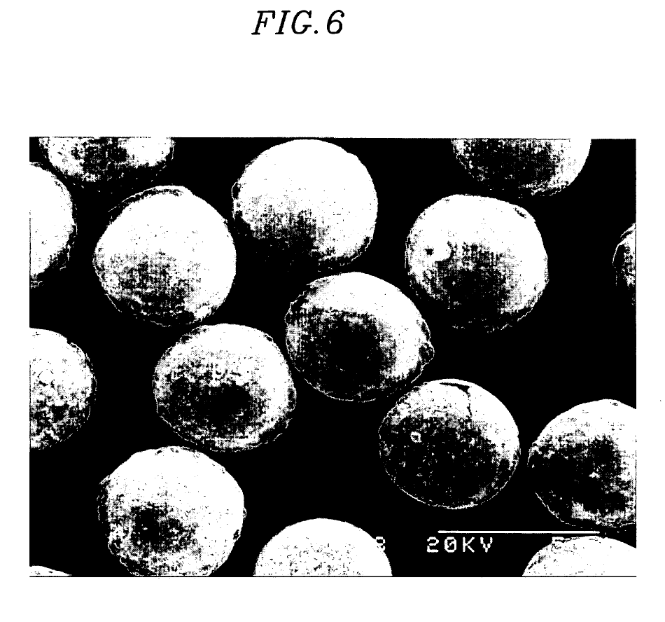

FIG. 6 is a scanning electron microscope (SEM) photograph of the conductive electrode powder with a silica coating layer.

An address electrode and a plasma display panel were fabricated by the same method as that of Comparative Example 1, except that 29.8 wt % of a photosensitive vehicle and 65 wt % of a conductive powder prepared according to Comparative Example 1, 3 wt % of PbO, 2 wt % of B₂O₃, and 0.2 wt % of silica were mixed to prepare a paste.

### Example 2

An address electrode and a plasma display panel were fabricated by the same method as that of Comparative Example 1, except that a photosensitive vehicle was prepared by mixing 5 wt % of a silica solution including 15 wt % of silica particles with an average particle diameter of 50 nm (water glass) (made by Ferro Co.) and 95 wt % of a photosensitive vehicle prepared according to Comparative Example 1.

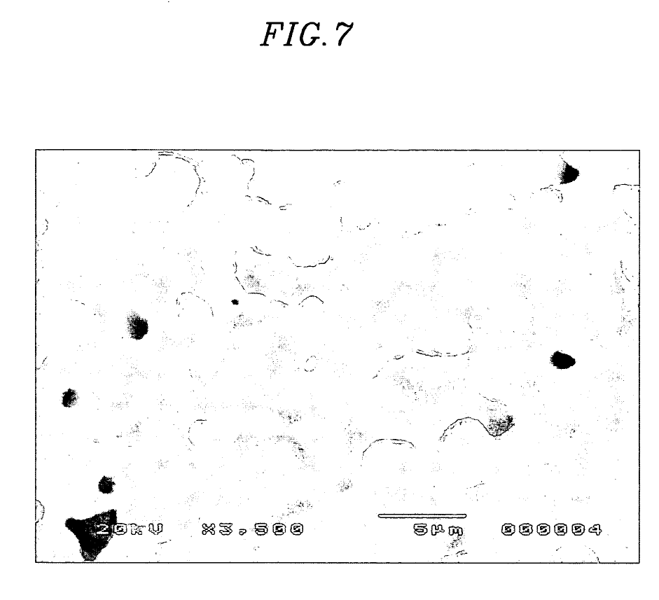

FIG. 7 is a scanning electron microscope (SEM) photograph of the surface of an address electrode according to Example 2 after firing it.

### Example 3

An address electrode and a plasma display panel were fabricated by the same method as that of Example 2, except that 5 wt % of a silica solution including 15 wt % of silica particles with an average particle diameter of 200 nm (water glass) (made by Ferro Co.) was used.

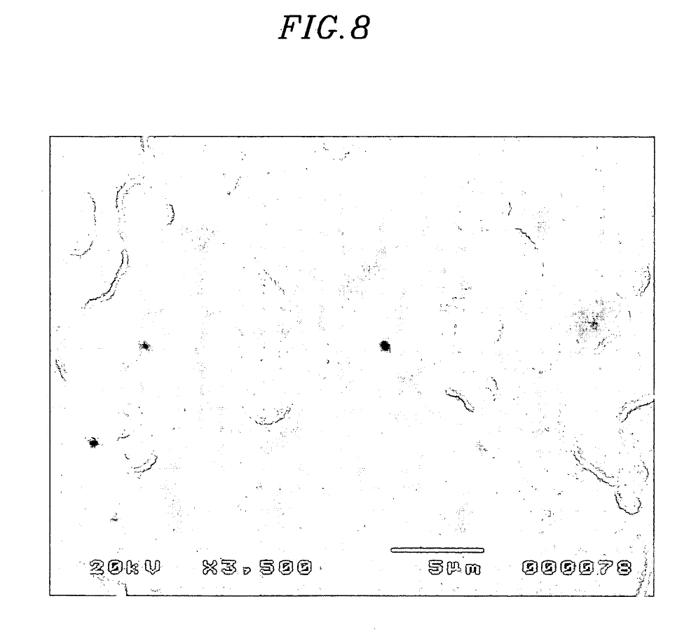

FIG. 8 is a scanning electron microscope (SEM) photograph of the surface of an address electrode according to Example 3, after firing it.

### Example 4

An address electrode and a plasma display panel were fabricated by the same method as that of Example 2, except that 5 wt % of an alumina solution including 15 wt % of alumina particles with an average particle diameter of 150 nm (water glass) (made by Ferro Co.) was used.

### Example 5

An address electrode and a plasma display panel were fabricated by the same method as that of Example 2, except that 5 wt % of a zirconia solution including 15 wt % of zirconia particles with an average particle diameter of 150 nm (water glass) (made by Ferro Co.) was used.

As shown in FIG. 6, an electrode conductive powder prepared according to Example 1 of the present invention had a silica coating layer.

In addition, comparing SEM photographs of FIGS. 5, 7, and 8, an address electrode fabricated according to Comparative Example 1 in FIG. 5 had relatively larger particles due to agglomeration of the silver particles during the firing, while those fabricated according to Examples 2 to 3 in FIGS. 7 and 8 had smaller and more uniform particles due to a silica layer isolating silver particles to prevent them from agglomerating during the firing. In this way, an electrode formed of small and uniform silver particles can facilitate excellent resolution.

In addition, color indexes of a panel glass, which neighbors an electrode terminal fabricated according to Comparative Example 1 and Examples 2 and 3, were measured using a camera (Model No. CM-2600D (Minolta Co.)). Electrical conductivity of the address electrodes after breaking away the silica layers thereon with a pressure was also measured. The results are provided in Table 1.

TABLE 1

| | Line Resistance | Color Index (b*) |
|---|---|---|
| Comparative | 30 ohms | 8.0684 |
| Example 1 | | |
| Example 2 | 35 ohms | 0.4621 |
| Example 3 | 40 ohms | 0.8999 |

As shown in Table 1, a plasma display panel including an electrode of the embodiment of the present invention had an improved color index.

Therefore, the present invention can provide a conductive electrode powder free from corrosion such as oxidation and sulfurization, migration such as ionization, and yellowing of a panel electrode of the present invention such as colloidalization, while simultaneously maintaining electrical conductivity of an electrode fabricated thereof.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A conductive electrode powder, comprising:
electroconductive metal particles; and
an inorganic oxide coating layer covering the surface of the electroconductive metal particles.

2. The conductive electrode powder of claim 1, wherein the electroconductive metal particles are at least one selected from the group consisting of silver (Ag), gold, palladium, platinum, copper, aluminum, tungsten, molybdenum, alloys thereof, and combinations thereof.

3. The conductive electrode powder of claim 1, wherein the electroconductive metal particles have an average particle diameter ranging from 10 nm to 5 μm.

4. The conductive electrode powder of claim 1, wherein the inorganic oxide coating layer has a thickness of less than or equal to 1 μm.

5. The conductive electrode powder of claim 1, wherein the inorganic oxide comprises at least one selected from the group consisting of silica, alumina, titania, zirconia, and combinations thereof.

6. A method of preparing a conductive electrode powder, comprising:
preparing an inorganic oxide dispersion by dispersing inorganic oxide particles in a dispersion solvent;
mixing electroconductive metal particles with the inorganic oxide dispersion to obtain a mixture; and
forming a powder from the mixture to obtain the conductive electrode powder.

7. The method of claim 6, wherein the powder is formed by spraying the mixture and firing the sprayed mixture.

8. The method of claim 7, wherein the spraying uses a thermal spraying method.

9. The method of claim 6, wherein the dispersion solvent is at least one selected from the group consisting of ethanol, trimethyl pentanediol monoisobutyrate (TPM), butyl carbitol (BC), butyl cellosolve (BC), butyl carbitol acetate (BCA), a terfenol isomer, terpineol (TP), toluene, texanol, and a combination thereof.

10. The method of claim 6, wherein the inorganic oxide particles are included in an amount of 5 to 30 parts by weight based on 100 parts by weight of the dispersion solvent.

11. The method of claim 6, wherein the inorganic oxide particles are included in an amount of 2 to 10 parts by weight based on 100 parts by weight of the electroconductive metal particles.

12. The method of claim 6, wherein the electroconductive metal particles are at least one selected from the group consisting of silver (Ag), gold, palladium, platinum, copper, aluminum, tungsten, molybdenum, alloys thereof, and combinations thereof.

13. The method of claim 6, wherein the inorganic oxide comprises at least one selected from the group consisting of silica, alumina, titania, zirconia, and combinations thereof.

14. A method of forming an electrode of a plasma display panel, comprising:
preparing a photosensitive vehicle by mixing a polymer resin, a photopolymerizable monomer, a photopolymerization initiator, and a solvent;
preparing a photosensitive composition by mixing a conductive electrode powder comprising electroconductive metal particles and an inorganic oxide coating layer covering the surface of the electroconductive metal particles with the photosensitive vehicle;
coating the photosensitive composition on a substrate; and
drying, exposing, developing, and firing the photosensitive composition on the substrate.

15. The method of claim 14, wherein the photosensitive composition comprises the conductive electrode powder and the photosensitive vehicle in a weight ratio of 50 to 80: 50 to 20.

16. The method of claim 14, wherein the photosensitive vehicle comprises the polymer resin, the photopolymerizable monomer, the photopolymerization initiator, and the solvent in a weight ratio of 10 to 40: 5 to 20: 1 to 10: 30 to 70.

17. The method of claim 14, wherein the polymer resin is selected from the group consisting of methacryl polymer, polyester acrylate, trimethylolpropane triacrylate, trimethylolpropane triethoxy triacrylate, cresol epoxy acrylate, and a combination thereof.

18. The method of claim 14, wherein the photopolymerizable monomer is selected from the group consisting of epoxy acrylate, polyester acrylate, methylacrylate, ethylacrylate, n-propylacrylate, isopropylacrylate, n-butylacrylate, sec-butylacrylate, sec-butylacrylate, iso-butylacrylate, tert-butylacrylate, n-pentylacrylate, allylacrylate, benzylacrylate, butoxyethylacrylate, butoxytriethyleneglycolacrylate, cyclohexylacrylate, dicyclopentanylacrylate, dicyclopentenylacrylate, 2-ethylhexylacrylate, glycerolacrylate, glycidylacrylate, hepadecafluorodecylacrylate, 2-hydroxyethylacrylate, isobonylacrylate, 2-hydroxypropylacrylate, isodecylacrylate, isooctylacrylate, laurylacrylate, 2-methoxyethylacrylate, methoxyethyleneglycolacrylate, methoxydiethyleneglycolacrylate, and combinations thereof.

19. The method of claim 14, wherein the photopolymerization initiator is selected from the group consisting of benzophenone, methyl o-benzoyl benzoate, 4,4-bis(dimethylamine)benzophenone, 4,4-bis(diethylamino)benzophenone, 4,4-dichlorobenzophenone, 4-benzoyl-4-methyldiphenyl ketone, dibenzyl ketone, fluorenone, 2,2-diethoxyacetophenone, 2,2-dimethoxy-2-phenylacetophenone, 2-hydroxy-2-methylpropinophenone, p-t-butyldichloroacetophenone, thioxanthone, 2-methylthioxanthone, 2-chlorothioxanthone, 2-isopropylthioxanthone, diethylthioxanthone, benzyldimethyl kethanol, benzylmethoxyethyl acetal, benzoin, benzoin methyl ether, benzoin butyl ether, anthraquinone, 2-t-butyl anthraquinone, 2-amylanthraquinone, β-chloroanthraquinone, anthrone, benzanthrone, dibenzosverone, methyleneanthrone, 4-azidebenzalacetophenone, 2,6-bis(p-azidebenzylidene) cyclohexanone, 2,6-bis(p-azidebenzylidene)-4-methylcyclohexanone, 2-phenyl-1,2-butadione-2-(o-methoxycarbonyl) oxime, 2,3-bis(4-diethylaminobenzal) cyclopentanone, 2,6-bis(4-dimethylaminobenzal) cyclohexanone, 2,6-bis(4-dimethylaminobenzal)-4-methylcyclohexanone, Mihira ketone, 4,4-bis(diethylamino)-benzophenone, 4,4-bis(dimethylamino) chalcone, 4,4-bis(diethylamino)chalcone, p-dimethylaminocynnamilidene indanone, p-dimethylamino benzylidene indanone, 2-(p-dimethylaminophenylvinylene)-isonaphtothiazole, 1,3-bis(4-dimethylaminobenzal)acetone, 1,3-carbonyl-bis(4-diethylaminobenzal)acetone, 3,3-carbonyl-bis(7-diethylaminocumaline), N-phenyl-N-ethylethanolamine, N-phenylethanolamine, N-tolyldiethanolamine, N-phenylethanolamine, isoamyl dimethylaminobenzoate, isoamyl diethylaminobenzoate, 3-phenyl-5-benzoylthio-tetrazol, 1-phenyl-5-ethoxycarbonylthio-tetrazol, and combinations thereof.

20. A method of forming an electrode of a plasma display panel, comprising:
preparing a photosensitive vehicle by mixing a polymer resin, a photopolymerizable monomer, a photopolymerization initiator, a solvent, and inorganic oxide;
preparing a photosensitive composition by mixing electroconductive metal particles and the photosensitive vehicle;
coating the photosensitive composition on a substrate; and
drying, exposing, developing, and firing the photosensitive composition on the substrate.

21. A plasma display panel comprising:
a first plate comprising:
a first substrate;
address electrodes formed on the first substrate;
a dielectric layer covering the address electrodes;
barrier ribs formed on the dielectric layer; and
phosphor layers positioned in discharge cells compartmentalized by the barrier ribs; and
a second plate facing the first plate, the second plate comprising:
a second substrate;
display electrodes comprising transparent electrodes and bus electrodes;
a transparent dielectric layer covering the display electrodes; and
a protective layer formed on the dielectric layer;
at least one of the address electrodes and the bus electrodes comprising electroconductive metal particles and an inorganic oxide coating layer covering the surface of the electroconductive metal particles.

22. The plasma display panel of claim 21, wherein the inorganic oxide coating layer comprises at least one selected from the group consisting of silica, alumina, titania, zirconia, and combinations thereof.
